(19) United States
(12) Patent Application Publication
(10) Pub. No.: US 2024/0274724 A1
(43) Pub. Date: Aug. 15, 2024

(54) UNIFORM SIGE CHANNEL IN NANOSHEET ARCHITECTURE

(71) Applicant: Applied Materials, Inc., Santa Clara, CA (US)

(72) Inventors: Jody A. Fronheiser, Delmar, NY (US); Sai Hooi Yeong, Cupertino, CA (US); Andre P. Labonte, Mechanicville, NY (US); Joseph Francis Shepard, JR., Saratoga Springs, NY (US); David Collins, Delmar, NY (US); Ning Li, San Jose, CA (US)

(73) Assignee: Applied Materials, Inc., Santa Clara, CA (US)

(21) Appl. No.: 18/414,844

(22) Filed: Jan. 17, 2024

Related U.S. Application Data
(60) Provisional application No. 63/444,631, filed on Feb. 10, 2023.

(51) Int. Cl. H01L 29/786; H01L 21/8238; H01L 27/088; H01L 29/06; H01L 29/10; H01L 29/423; H01L 29/66; H01L 29/775

(52) U.S. Cl. CPC H01L 29/78696; H01L 21/823807; H01L 21/823814; H01L 21/823828; H01L 27/088; H01L 29/0673; H01L 29/1054; H01L 29/42392; H01L 29/66439; H01L 29/66545; H01L 29/775

(57) ABSTRACT

Horizontal gate-all-around devices and methods of manufacture are described. The hGAA devices comprise a semiconductor material between source regions and drain regions of the device. The method includes formation of a cladding material on a first material followed by forming a tensile film on the cladding layer. The strained tensile film results in a uniform SiGe channel.

### CROSS-REFERENCE TO RELATED APPLICATIONS

This application claims priority to U.S. Provisional Application No. 63/444,631, filed Feb. 10, 2023, the entire disclosure of which is hereby incorporated by reference herein.

### TECHNICAL FIELD

Embodiments of the present disclosure generally relate to semiconductor devices and more particularly to horizontal gate all around device structures and methods and apparatus for forming horizontal gate all around device structures.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a horizontal gate all around (hGAA) structure. The hGAA device structure includes several lattice matched channels suspended in a stacked configuration and connected by source/drain regions. The inventors believe that the hGAA structure provides good electrostatic control and can find broad adoption in complementary metal oxide semiconductor (CMOS) wafer manufacturing.

Logic gate performance is related to the characteristics of the materials used as well as the thickness and area of the structural layers. As some gate characteristics are adjusted to accommodate device scaling, however, challenges arise. Furthermore, the space confinement between wires on a horizontal gate-all-around (hGAA) device limits the thickness of the gate dielectric material for I/O transistors.

A silicon germanium (SiGe) channel is one attractive feature for a gate-all-around (GAA) (nanowire or nanosheet) to achieve a high mobility PMOS. One method is to form a uniform SiGe layer around the silicon nanosheet and continue with gate stack processing. This will enhance performance but suffers from low compressive strain in the channel and will not fully demonstrate the benefits of a SiGe channel. In planar technologies, SiGe PFET channels have been proven in mass production by so-called condensation. In this approach, the SiGe layer is oxidized at high temperature, typically 1000° C. or higher, which is sufficient to consume the SiGe layer and diffuse the Ge for a uniform SiGe film. Traditional condensation at 1000° C., however, is too hot for GAA architecture. For example, dopants at the junction will diffuse and degrade device performance.

Accordingly, there is a need for improved methods for forming PMOS electronic devices.

### SUMMARY

One or more embodiments of the disclosure are directed to methods of forming a semiconductor device. In an embodiment, the method comprises: selectively etching a superlattice structure on a substrate, the superlattice structure comprising a plurality of first layers of a first material and a corresponding plurality of second layers of a second material alternatingly arranged in a plurality of stacked pairs extending between a source region and a drain region, wherein selectively etching the superlattice structure removes each of the plurality of second layers to form a plurality of voids in the superlattice structure and a plurality of nanosheets comprising the plurality of first layers; forming a cladding material around each of the plurality of the nanosheets comprising the plurality of first layers; forming a tensile film around the cladding material, the tensile film having a tensile stress and imparting a tensile strain on the plurality of nanosheets; optionally, curing the tensile film; thermally treating the plurality of nanosheets; and removing the tensile film to form a plurality of nanosheets of cladding material.

Further embodiments are directed to an electronic device. In an embodiment, the electronic device comprises: a PMOS comprising a uniform SiGe channel between a source region and a drain region; and a NMOS comprising a Si channel between a source region and a drain region.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a process flow diagram of a method for forming a semiconductor device in accordance with some embodiments of the present disclosure;

FIG. 2 illustrates a cross-section view of device according to one or more embodiments;

FIG. 3 illustrates a cross-section view of device according to one or more embodiments:

FIG. 4 illustrates a cross-section view of device according to one or more embodiments;

FIG. 5 illustrates a cross-section view of device according to one or more embodiments;

FIG. 6 illustrates a cross-section view of device according to one or more embodiments;

FIG. 7 illustrates a cross-section view of device according to one or more embodiments;

FIG. 8 illustrates a cross-section view of device according to one or more embodiments;

FIG. 9 illustrates a cross-section view of device according to one or more embodiments;

FIG. 10 illustrates a cross-section view of device according to one or more embodiments; and

FIG. 11 illustrates a schematic representation of a cluster tool according to one or more embodiments of the disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is contact between elements, and there may be intervening elements or layers. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate. In one or ore more embodiments, the gate surrounds all of the nanosheets between the bottom substrate and above channels.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated I_{D}. Drain-to-source voltage is designated VDs. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10-9 meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

A silicon germanium (SiGe) channel is one attractive feature for a gate-all-around (GAA) (Nanowire or Nanosheet) to achieve high mobility PMOS. One method is to form a uniform SiGe layer around the silicon nanosheet and continue with gate stack processing. This will enhance performance but suffers from low compressive strain in the channel and will not fully demonstrate the benefits of a SiGe channel. In planar technologies, SiGe PFET channels have been proven in mass production by so-called condensation. In this approach, the SiGe layer is oxidized at high temperature, typically 1000° ° C. or higher, which is sufficient to consume the SiGe layer and diffuse the Ge for a uniform SiGe film. Traditional condensation at 1000° C., however, is too hot for GAA architecture. For example, dopants at the junction will diffuse and degrade device performance.

One or more embodiments advantageously provide methods of forming a uniform SiGe channel in a gate-all-around (GAA) device with a low thermal budget and no silicon core. More specifically, a uniform SiGe channel is formed at low temperature using a tensile strained film. Unlike with conventional high temperature anneals that degrade junction designs, the method of one or more embodiments advantageously results in minimal to no degradation of the GAA device.

One or more embodiments of the disclosure are directed to methods of forming horizontal gate-all-around (GAA) devices. Some embodiments advantageously provide integrated methods for forming complementary metal-oxide semiconductor (CMOS) devices with a uniform SiGe channel for PMOS while maintaining silicon channel material for NMOS. In some embodiments, the uniform SiGe channel is formed at low temperature using a tensile strained layer, resulting in minimal to no degradation of the GAA device.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, transistors, e.g., gate all-around transistors, are fabricated using a standard process flow. In some embodiments, a method for forming the hGAA devices is augmented to use a tensile strained layer.

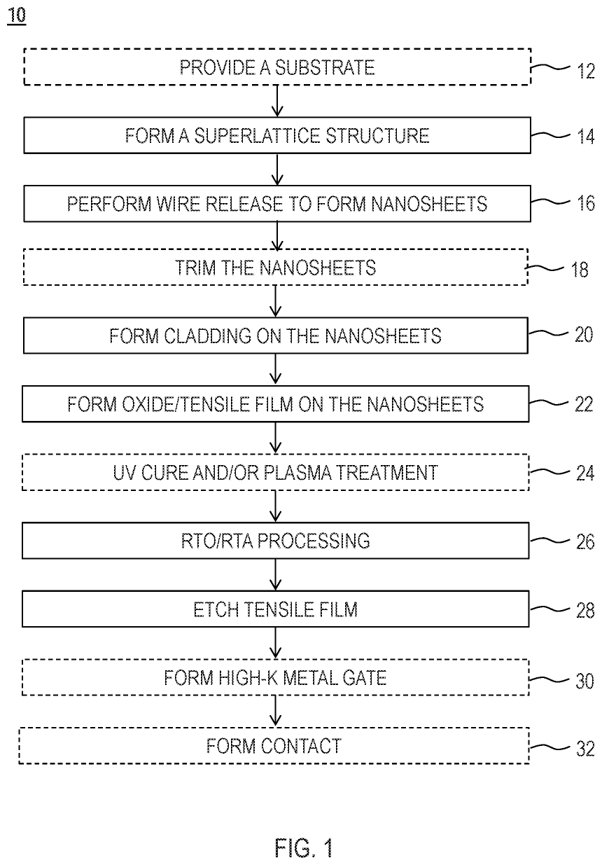

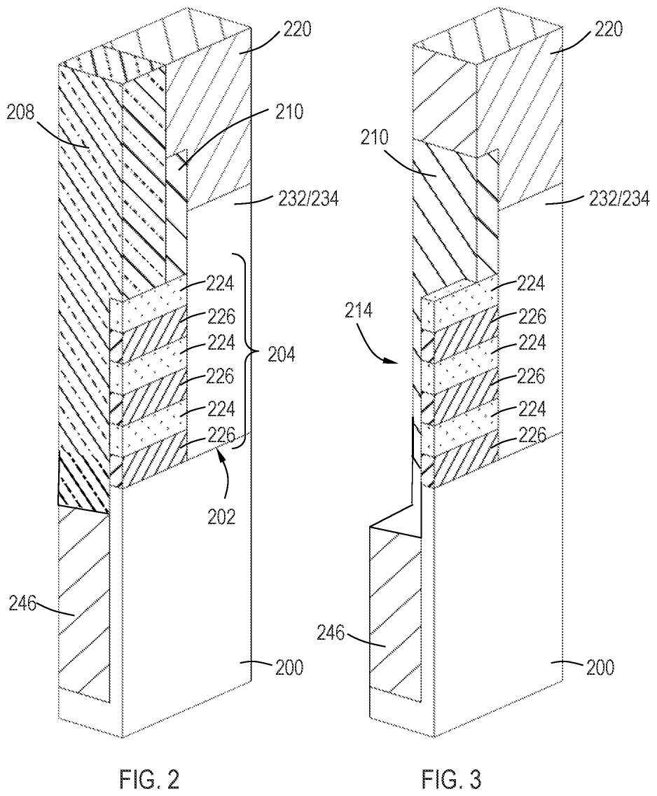

FIG. 1 illustrates a process flow diagram for a method 10 for forming a semiconductor device in accordance with some embodiments of the present disclosure. The method 10 is described below with respect to FIGS. 2-10, which depict the stages of fabrication of semiconductor structures, specifically gate-all-around (GAA) devices) in accordance with some embodiments of the present disclosure. The method 10 of one or more embodiments may be part of a multi-step fabrication process of a semiconductor device. Accordingly, the method may be performed in any suitable process chamber coupled to a cluster tool. The cluster tool may include process chambers for fabricating a semiconductor device, such as chambers configured for etching, deposition, atomic layer deposition (ALD), physical vapor deposition (PVD), chemical vapor deposition (CVD), oxidation, or any other suitable chamber used for the fabrication of a semiconductor device.

The method 10 begins at 12, by providing a substrate 200 having a top surface 202 (as illustrated in FIG. 2). As used in this manner, the term “providing” means that the substrate 200 is made available for processing. For example, the substrate 200 can be provided by being placed within a suitable processing chamber. In some embodiments, the substrate 200 may be a bulk semiconductor substrate. The term bulk semiconductor substrate refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, or other suitable semiconducting materials. In some embodiments, the semiconductor material is silicon (Si). In some embodiments, the semiconductor material may be a doped material, such as n-doped silicon (n-Si), or p-doped silicon (p-Si). In some embodiments, the substrate may be doped using any suitable process such as an ion implantation process. In some embodiments, the substrate may be doped to provide a high dose of dopant at a first location of the surface of the substrate 200 in order to prevent parasitic bottom device turn on. The superlattice structure is formed atop the first location. For example, in some embodiments, the surface of the substrate may have a dopant density about 10¹⁸ atoms/cm³ to about 10¹⁹ atoms/cm³.

At operation 14 of method 10, at least one superlattice structure 204 is formed atop the top surface 202 of the substrate 200 (as depicted in FIG. 2). The superlattice structure 204 comprises a plurality of first layers 224 and a corresponding plurality of second layers 226 alternatingly arranged in a plurality of stacked pairs. In some embodiments the plurality of stacked groups of layers comprises a silicon (Si) and silicon germanium (SiGe) group. In some embodiments, the plurality of first layers 224 and corresponding plurality of second layers 226 can comprise any number of lattice matched material pairs suitable for forming a superlattice structure 204. In some embodiments, the plurality of first layers 224 and corresponding plurality of second layers 226 comprise from 2 to 50 pairs, or from 2 to 20 pairs of lattice matched materials.

Typically, a parasitic device will exist at the bottom of the superlattice structure 204. In some embodiments, implant of a dopant in the substrate, as discussed above, is used to suppress the turn on of the parasitic device. In some embodiments, the substrate 200 is etched so that the bottom portion of the superlattice structure 204 includes a substrate portion which is not removed, allowing the substrate portion to act as the bottom release layer of the superlattice structure 204.

The thicknesses of the first layers 224 and second layers 226 in some embodiments are in the range of about 2 nm to about 50 nm, or in the range of about 3 nm to about 20 nm. In some embodiments, the average thickness of the first layers 224 is within 0.5 to 2 times the average thickness of the second layers 226.

In some embodiments, a dielectric material 246 is deposited on the substrate 200 using conventional chemical vapor deposition methods. In some embodiments, the dielectric material 246 is recessed below the top surface 202 of the substrate 200 so that the bottom portion of the superlattice structure 204 is formed from the substrate 200.

In some embodiments, a replacement gate structure (e.g., a dummy gate structure 208) is formed over the superlattice structure 204. The dummy gate structure 208 defines the channel region of the transistor device. The dummy gate structure 208 may be formed using any suitable conventional deposition and patterning process known in the art.

In some embodiments, sidewall spacers 210 are formed along outer sidewalls of the dummy gate structure 208. The sidewall spacers 210 of some embodiments comprise suitable insulating materials known in the art, for example, silicon nitride (SiN), silicon oxide (SiOx), silicon oxynitride (SiON), silicon carbide (SiC), or the like. In some embodiments, the sidewall spacers 210 are formed using any suitable conventional deposition and patterning process known in the art, such as atomic layer deposition, plasma enhanced atomic layer deposition, plasma enhanced chemical vapor deposition or low-pressure chemical vapor deposition.

In some embodiments, an embedded source region 232 and drain region 234 form in a source trench and a drain trench, respectively. In some embodiments, the source region 232 is formed adjacent a first end of the superlattice structure 204 and the drain region 234 is formed adjacent a second, opposing end of the superlattice structure. In the embodiment illustrated in FIG. 2, the one of the source region 232 or drain region 234 is not shown at the front face of the superlattice structure 204. The other end of the superlattice structure 204 has the other of the source region 232 or drain region 234. In some embodiments, the source region 232 and/or drain region 234 are formed from any suitable semiconductor material, such as but not limited to silicon (Si), germanium (Ge), silicon germanium (SiGe), or the like. In some embodiments, the source region 232 and drain region 234 may be formed using any suitable deposition process, such as an epitaxial deposition process.

In some embodiments, an inter-layer dielectric (ILD) layer 220 is blanket deposited over the substrate 200, including the source/drain regions 232, 234, the dummy gate structure 208, and the sidewall spacers 210. The ILD layer 220 may be deposited using a conventional chemical vapor deposition method (e.g., plasma enhanced chemical vapor deposition and low-pressure chemical vapor deposition). In an embodiment, ILD layer 220 is formed from any well-known dielectric material such as, but not limited to undoped silicon oxide, doped silicon oxide (e.g., BPSG, PSG), silicon nitride (SiN), and silicon oxynitride (SiON). ILD layer 220 is then polished back using a conventional chemical mechanical planarization method to expose the top of the dummy gate structure 208. In some unillustrated embodiments, the ILD layer 220 is polished to expose the top of the dummy gate structure 208 and the top of the sidewall spacers 210.

In some embodiments, as illustrated in FIG. 3, the dummy gate structure 208 is removed to expose the channel region 214 of the superlattice structure 204. The ILD layer 220 protects the source/drain regions 232, 234 during the removal of the dummy gate structure 208. The dummy gate structure 208 may be removed using a conventional etching method such plasma dry etch or a wet etch. In some embodiments, the dummy gate structure 208 comprises poly-silicon and the dummy gate structure is removed by a selective etch process. In some embodiments, the dummy gate structure 208 comprises poly-silicon and the superlattice structure 204 comprises alternating layers of silicon (Si) and silicon germanium (SiGe).

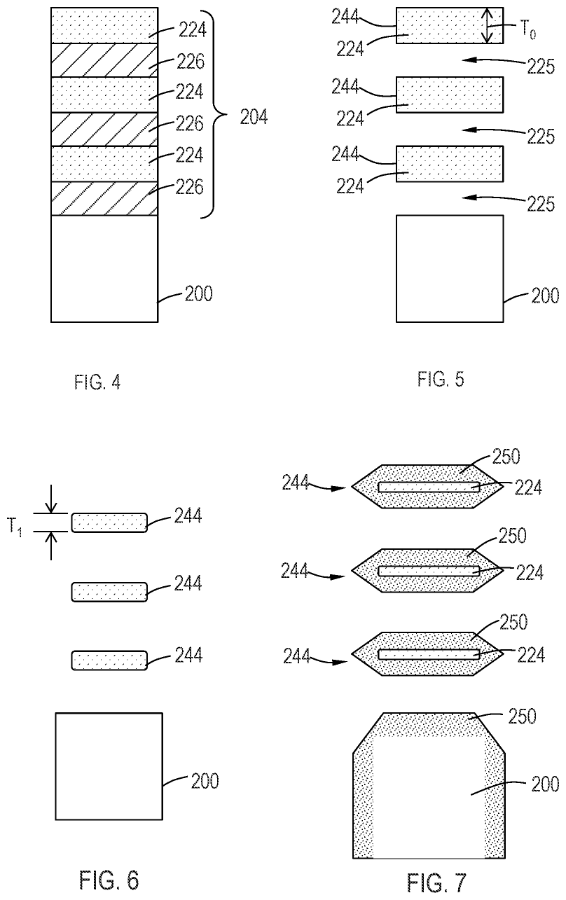

FIG. 4 illustrates the relevant portion of the electronic device of FIG. 3 showing an end-on view of the superlattice structure 204 with alternating layers of first material 224 and second material 226. In process 16 of method 10, as illustrated in FIG. 5, a wire release process selectively etches between the first material 224 layers in the superlattice structure 204. The wire release process forms a plurality of voids 225 between the first material 224 layers resulting in a plurality of nanosheets 244 comprising the first layers 224 extending between the source region and drain regions.

For example, where the superlattice structure 204 is composed of silicon (Si) layers and silicon germanium (SiGe) layers, the silicon germanium (SiGe) is selectively etched to form channel nanowires (also referred to as nanosheets). The release layers (second material 226), for example silicon germanium (SiGe), may be removed using any well-known etchant that is selective to the layers of the semiconductor material layers 224 where the etchant etches the layers of release layers (second material 226) at a significantly higher rate than the layers of semiconductor material layers (first material 224). In some embodiments, a selective dry etch or wet etch process may be used. In some embodiments, where the semiconductor material layers (first material 224) are silicon (Si) and the release layers (second material 226) are silicon germanium (SiGe), the layers of silicon germanium (SiGe) may be selectively removed using a wet etchant such as, but not limited to aqueous carboxylic acid/nitric acid/HF solution and aqueous citric acid/nitric acid/HF solution. The removal of the release layers (second material 226) leaves voids 225 between the semiconductor material layers (first material 224). The voids 225 between the semiconductor material layers (first material 224) have a thickness of about 3 nm to about 20 nm. The remaining semiconductor material layers form a vertical array of channel nanowires that are coupled to the source/drain regions 232, 234. The channel nanowires run parallel to the top surface 202 of the substrate 200 and are aligned with each other to form a single column of channel nanowires. The formation of the source region 232 and drain region 234 and the formation of an optional lateral etch stop layer (not shown) advantageously provide self-alignment and structural integrity in the formation of the channel structure.

At optional operation 18, as illustrated in FIG. 6, the nanosheets 244 are exposed to an optional process in which the nanosheets 244 comprising the first material 224 are trimmed from an initial thickness T₀ (as shown in FIG. 5) to nanosheets 244 having a reduced thickness T₁ (as shown in FIG. 6).

The nanosheets 244 are trimmed by any suitable etch process known to the skilled artisan that is compatible with the first material 224. In some embodiments, the nanosheets 244 are trimmed by exposure to a wet etch process, such as aqueous alkaline media like KOH—, NaOH— or TMAH-solutions. In some embodiments, the nanosheets 244 are trimmed by exposure to a dry etch process. In one or more embodiments, the dry etch process includes exposing the nanosheets 244 to common gases for etching the silicon, reactive ion etching (RIE) with a remote plasma source, ammonia (NH₃), and hydrogen (H₂).

The reduction in thickness of the nanosheets according to some embodiments is greater than or equal to 50% of the initial thickness T₀. In some embodiments, the initial thickness T₀ is in the range of 4 nm to 10 nm, or in the range of 5 nm to 9 nm, or in the range of 6 nm to 8 nm. In some embodiments, the reduced thickness T₁ is in the range of ⅓ to ⅕ of initial thickness T₀, or in the range of from 1 nm to 3 nm. In some embodiments, trimming the nanosheets reduces the thickness of the nanosheets from an initial thickness T₀ in the range of from 6 nm to 8 nm to a reduced thickness T₁ in the range of from 1 nm to 3 nm or in a range of from 2 nm to 3 nm.

At operation 20, a cladding material 250 is formed around each of the plurality of first layers 224 of nanosheets 244. The cladding material 250 is formed on the nanosheets whether or not the optional operation 18 is performed. The cladding material 250 can be formed by any suitable process known to the skilled artisan. In some embodiments, the cladding material 250 comprises silicon germanium (SiGe) or germanium (Ge). In one or more embodiments, the cladding material 250 comprises germanium in a range of 0% to 100% or in a range of from 15% to 50%.

In some embodiments, the cladding material 250 is epitaxially grown on a plurality of first layers 224 of the nanosheets 244. In one or more embodiments, the cladding material may be fabricated via chemical vapor deposition (CVD) epitaxy with a temperature ranging from 450° C. and 850° C.

In one or more embodiments, the cladding material 250 has any suitable thickness. In some embodiments, the cladding material 250 has a thickness in a range of from 2 nm to 5 nm.

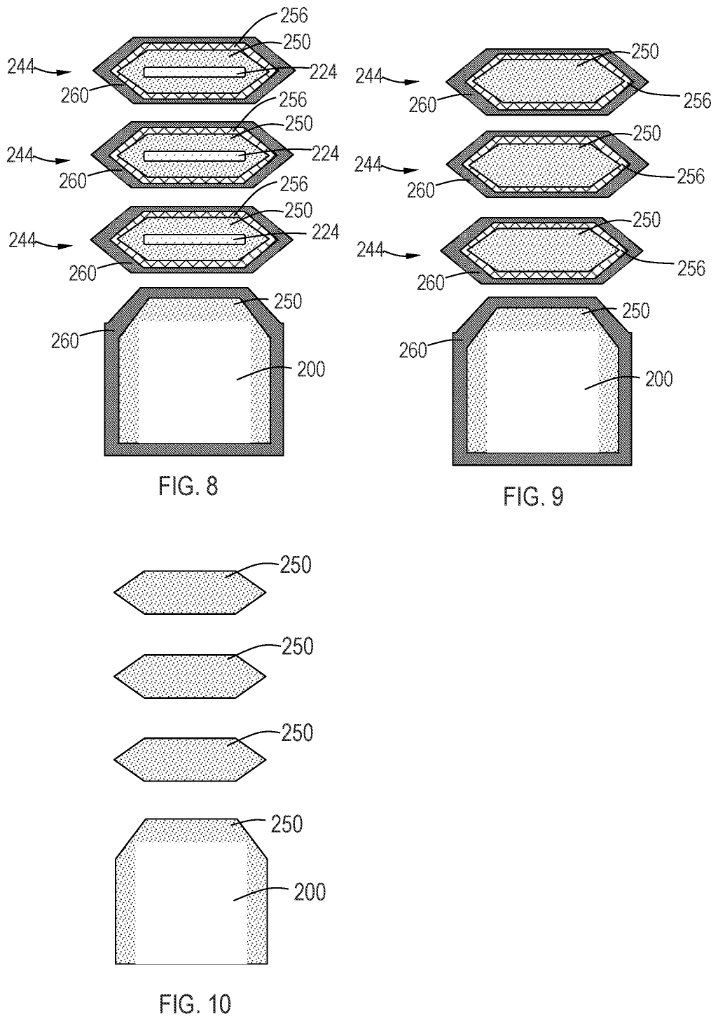

Referring to FIG. 1 and FIG. 8, at operation 22, an etch stop layer 256 and a tensile film 260 are formed around the cladding material 250. The etch stop layer 256 may comprise any suitable material known to the skilled artisan. In one or more embodiments, the etch stop layer 256 is an oxide material. In one or more embodiments, the etch stop layer 256 has a thickness in a range of from 0 nm to 3 nm, or in a range of from 0 nm to 2 nm, or in a range of from 0 nm to 1 nm.

In one or more embodiments, the etch stop layer 256 comprises an oxide of the cladding material 250 and can be formed by any suitable oxidation process known to the skilled artisan. In some embodiments, the etch stop layer 256 is formed by an atomic layer deposition (ALD) process with low processing temperature ranging from 250° C. to 450° C. and in some cases with plasma treatment or enhanced function. In some embodiments, the etch stop layer 256 is formed by rapid plasma oxidation (RPO) of the cladding material 250. In some embodiments, the RPO process exposes the substrate 200 to an oxygen-containing plasma (e.g., molecular oxygen (O₂), ozone (O₃)) at a temperature in the range of 350° C. to 9000° C., or at a temperature in the range of from 350° C. to 800° C. In some embodiments, the RPO process exposes the substrate 200 to an oxygen-containing plasma (e.g., molecular oxygen (O₂), ozone (O₃)) at a pressure ranging from 5 torr to 600 torr.

In one or more embodiments, the tensile film 260 advantageously enhances germanium (Ge) diffusion to form a uniform silicon germanium (SiGe) channel. Additionally, the tensile film 260 helps control channel thickness by preventing oxidation of the silicon germanium (SiGe).

The tensile film 260 may comprise any suitable material known to the skilled artisan. In one or more embodiments, the tensile film 260 comprises one or more of silicon nitride (SiN), amorphous silicon (a-Si), poly-silicon, and silicon carbonitride (SiCN).

In one or more embodiments, the tensile film 260 has a tensile stress in a range of from 500 MPa to 2000 MPa, including in a range of from 600 MPa to 1700 MPa. As used herein, the term “tensile stress” refers to the force the tensile film provides, while the term “tensile strain” is what force the film applies to the substrate material.

The tensile film 260 may have any suitable thickness. In one or more embodiments, the tensile film 260 has a thickness in a range of from 25 nm to 50 nm. In such embodiments, without intending to be bound by theory, it is thought that the tensile film 260 is deposited to effectively fill the dummy gate region and provide the highest level of strain to the nanosheets. In other embodiments, the tensile film has a thickness in a range of from 1 nm to 4 nm.

Referring to FIG. 1, at operation 24, the device is optionally cured using ultraviolet (UV) light at a temperature in a range of from about 300° C. to about 500° C., including a range of about 400° C. to about 480° C.

In other embodiments, at operation 24, no UV cure is used, but, instead, the device is optionally subjected to a plasma treatment. In one or more embodiments, the plasma comprises one or more of hydrogen (H₂), ammonia (NH₃), and nitrogen (N₂).

In still further embodiments, at operation 24, no UV cure or plasma treatment is performed.

With reference to FIG. 1 and FIG. 9, at operation 26 of method 10, the nanosheets 244 are subjected to a rapid thermal oxidation (RTO) process and a rapid thermal anneal (RTA) process. In some embodiments, the RTO/RTA process ramps the temperature of the substrate from a start temperature (e.g., room temperature) to a maximum temperature in a range of 700° C. to 1050° C., including in a range of from 700° C. to 850° C., at a rate greater than or equal to 25° C./second, 50° C./second or higher at 5-780 torr during of 1-5 minutes. During the rapid thermal oxidation (RTO) process/rapid thermal anneal (RTA) process, the process environment of some embodiments comprises one or more of oxygen (O₂), ozone (O₃), hydrogen (H₂), in some cases under mixture of O₂/N₂, or H₂/O₂, or H₂/N₂ gases.

The rapid thermal oxidation (RTO) process/rapid thermal anneal (RTA) process of operation 26 results in rearrangement of the germanium (Ge) atoms in the nanosheets 244 so that the cladding material 250 effectively replaces the first layers 224. In one or more embodiments, removing the first material from the plurality of nanosheets comprises exposing the semiconductor device to one or more of a rapid thermal oxidation (RTO) process and a rapid thermal anneal (RTA) process to cause germanium (Ge) from the cladding material to diffuse into the first material, effectively removing/replacing the first layers. Without intending to be bound by theory, it is thought that that plurality of nanosheets 244 with cladding material 250 are strained (tensile film 260 pulls the lattice apart to allow more Ge intermixing/diffusion).

Referring to FIG. 1 and FIG. 10, at operation 28 of method 10, the tensile film 260 and oxide etch stop layer 156 are removed by any suitable etch process. In some embodiments, removing the etch stop layer 156 and the tensile film 260 comprises exposing the substrate to a solution of dilute hydrofluoric acid (˜1:100-1:150 HF:H₂O) at room temperature, or exposing the substrate to a solution of hot phosphoric acid (H₂PO₄) at about 165° C.

Referring to FIG. 1, operations 30 and 32 of method 10 represents one or more post-tensile film removal processing according to some embodiments. The one or more post-tensile film removal processes can by any of the processes known to the skilled artisan for completion of the hGAA devices. For example, in some illustrated embodiments, a capping layer may be formed or grown on the semiconductor material layers. The capping layer can be any suitable oxide formed by any suitable technique known to the skilled artisan. In some embodiments, the capping layer comprises a silicon capping layer.

In one or more unillustrated embodiments, a high-k dielectric layer may be formed on the capping layer. The high-k dielectric layer can be any suitable high-k dielectric material deposited by any suitable deposition technique known to the skilled artisan. The high-k dielectric layer of some embodiments comprises hafnium oxide. In some embodiments, a conductive material such as titanium nitride, tungsten, cobalt, aluminum, or the like may be formed on the high-k dielectric layer. The conductive material may be formed using any suitable deposition process such as atomic layer deposition (ALD) in order to ensure the formation of a layer having a uniform thickness around each of the semiconductor material layer.

In some unillustrated embodiments, a gate electrode may be formed on the substrate 200 and surrounds each of the doped semiconductor material layers. The gate electrode may be formed from any suitable gate electrode material known in the art. The gate electrode material is deposited using any suitable deposition process such as atomic layer deposition (ALD) to ensure that gate electrode is formed around and between each of the semiconductor material layers. The resultant device formed using the method described herein is a horizontal gate all around device, in accordance with an embodiment of the present disclosure. Some embodiments of the disclosure are directed to horizontal gate-all-around devices having a uniform silicon germanium (SiGe) channel.

Some embodiments of the disclosure are directed to electronic devices comprising a PMOS and an NMOS. The PMOS comprises a SiGe channel between a source and drain region and the NMOS comprises a Si channel between a source region and a drain region.

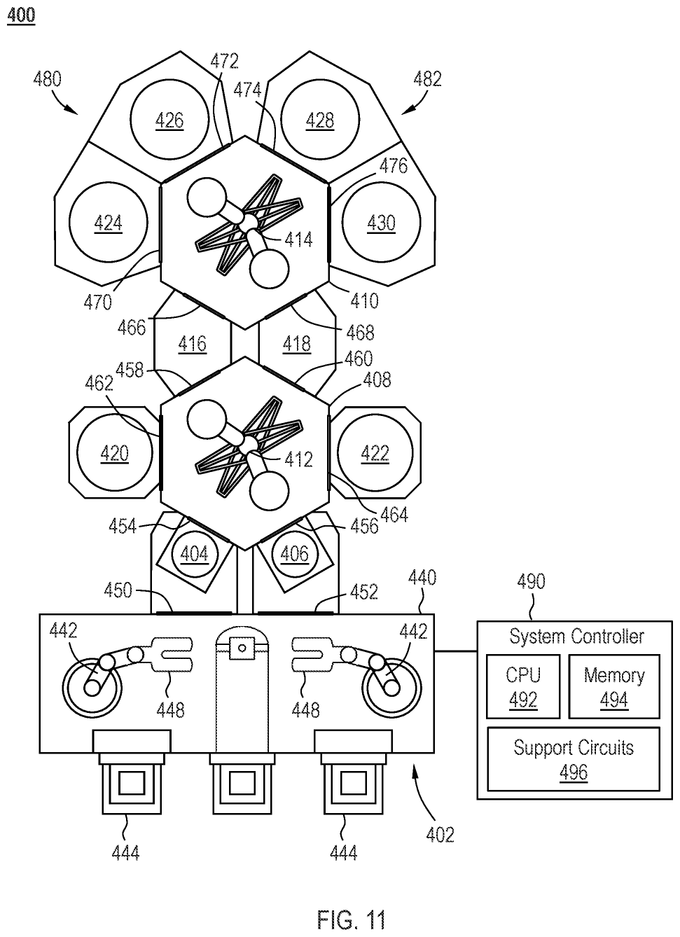

Some embodiments of the disclosure are directed to integrated processes which are performed within a single cluster tool. FIG. 11 is a schematic top-view diagram of an example multi-chamber processing system 400 according to one or more embodiments. FIG. 11 illustrates a schematic top-view diagram of an example of a multi-chamber processing system 400 according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 40 to 80 Torr) or vacuum environment without breaking the low pressure or vacuum environment between various processes performed on the wafers in the processing system 400. Accordingly, the processing system 400 may provide for an integrated solution for some processing of wafers.

In the illustrated example of FIG. 11, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
selectively etching a superlattice structure on a substrate, the superlattice structure comprising a plurality of first layers of a first material and a corresponding plurality of second layers of a second material alternatingly arranged in a plurality of stacked pairs extending between a source region and a drain region, wherein selectively etching the superlattice structure removes each of the plurality of second layers to form a plurality of voids in the superlattice structure and a plurality of nanosheets comprising the plurality of first layers;
forming a cladding material around each of the plurality of the nanosheets comprising the plurality of first layers;
forming a tensile film around the cladding material, the tensile film having a tensile stress and imparting a tensile strain on the plurality of nanosheets;
optionally, curing the tensile film;
thermally treating the plurality of nanosheets; and
removing the tensile film to form a plurality of nanosheets of cladding material.

2. The method of claim 1, wherein the first material comprises silicon (Si) and the second material comprises silicon germanium (SiGe).

3. The method of claim 1, wherein the cladding material comprises silicon germanium (SiGe).

4. The method of claim 3, wherein the cladding material comprises from 15% to 50% germanium (Ge).

5. The method of claim 1, further comprising forming an etch stop layer around the cladding material prior to forming the tensile film.

6. The method of claim 1, wherein the tensile film has a tensile stress in a range of from 500 MPa to 2000 MPa.

7. The method of claim 1, wherein thermally treating the plurality of nanosheets comprises exposing the semiconductor device to one or more of a rapid thermal oxidation (RTO) process, a rapid thermal anneal (RTA) process, and a rapid plasma oxidation (RPO) process, to cause germanium (Ge) from the cladding material to diffuse into the first material.

8. The method of claim 7, wherein the RTO/RTA process ramps the temperature of the substrate from a start temperature to a maximum temperature in a range of from 700° C. to 850° C.

9. The method of claim 8, wherein forming the etch stop layer comprises rapid plasma oxidation (RPO) of a portion of the cladding material.

10. The method of claim 1, wherein the tensile film is cured by UV at a temperature in a range of from 300° C. to about 500° C.

11. The method of claim 1, further comprising exposing the tensile film to a plasma treatment, the plasma comprising one or more of hydrogen (H₂), ammonia (NH₃), and nitrogen (N₂).

12. The method of claim 1, wherein removing the tensile film comprises etching.

13. The method of claim 1, wherein the tensile film has a tensile stress in the range of from 600 MPa to 1700 MPa.

14. The method of claim 1, wherein the tensile film comprises one or more of silicon nitride (SiN), amorphous silicon (a-Si), poly-silicon, and silicon carbonitride (SiCN).

15. The method of claim 1, wherein the tensile film has a thickness in a range of from 1 nm to 4 nm.

16. The method of claim 1, wherein the tensile film has a thickness in a range of from 25 nm to 50 nm.

17. The method of claim 1, further comprising trimming the plurality of nanosheets before forming the cladding material to reduce a thickness of the nanosheets from an initial thickness in the range of 6 nm to 8 nm to a reduced thickness in the range of 2 nm to 3 nm.

18. The method of claim 1, further comprising forming a high-k metal gate in contact with the plurality of nanosheets of cladding material.

19. The method of claim 1, further comprising forming the source region adjacent a first end of the superlattice structure and the drain region adjacent a second opposing end of the superlattice structure.

20. An electronic device comprising:
a PMOS comprising a uniform SiGe channel between a source region and a drain region; and
an NMOS comprising a Si channel between a source region and a drain region.
